(19) United States
(12) Patent Application Publication
(10) Pub. No.: US 2022/0397693 A1
(43) Pub. Date: Dec. 15, 2022

(54) PROXIMITY SENSOR

(71) Applicant: TURCK Holding GmbH, Halver (DE)

(72) Inventors: Michael Faber, Altena (DE); Karel Brauner, Halver (DE)

(21) Appl. No.: 17/834,955

(22) Filed: Jun. 8, 2022

(30) Foreign Application Priority Data
Jun. 10, 2021 (DE) 10 2021 114 948.7

(51) Int. Cl. G01V 3/10; H01F 27/28

(52) U.S. Cl. CPC G01V 3/10; H01F 27/2885

(57) ABSTRACT

A proximity sensor for the inductive detection of objects, including a housing with a front cap, a processing and receiving unit, comprising a printed circuit board, which is configured to connect to an external control and evaluation unit, and a coil carrier, on which at least one primary coil and at least one first secondary coil are arranged circumferentially wound and spaced apart in an axial direction of an axis extending axially through the housing, wherein the first secondary coil lies closer, in the axial direction, to the end face than the primary coil, wherein a second secondary coil is arranged on the coil carrier, wherein the primary coil is arranged between the first and second secondary coils, wherein a metallic shielding element is arranged in an axial area surrounding the second secondary coil and is not arranged in an axial area surrounding the first secondary coil.

### CROSS-REFERENCE TO PRIOR APPLICATIONS

This application claims benefit to German Patent Application No. DE 10 2021 114 948.7, filed on Jun. 10, 2021, which is hereby incorporated by reference herein.

### FIELD

The present invention relates to a proximity sensor.

### BACKGROUND

Proximity sensors that function inductively are known in the state of the art, for instance U.S. Pat. No. 8,188,730 B2 discloses a coil system with two coils which are mounted in a ferrite core. A proximity sensor is known from U.S. Pat. No. 5,952,822 A, in which a shielding of the two coils by means of a flat element on one side, on two sides or on three sides is proposed. Furthermore, WO 2016/037597 A1 discloses an electrically conductive shielding of the coils of a proximity sensor, in which a shielding cup is provided which surrounds the coil arrangement laterally and on the rear face, wherein the shielding cup transitions into an upper flange. Finally, a design of a proximity sensor has also become known from DE 10 057 773 A1, in which the secondary coils is divided into several partial coils arranged in the same plane in order to widen the proximity field, wherein the shielding of the primary coil lies symmetrically between the secondary coils.

### SUMMARY

In an embodiment, the present invention provides a proximity sensor for the inductive detection of objects, comprising a housing with a front cap, which forms a detection side of the proximity sensor, a processing and receiving unit, comprising a printed circuit board, which is configured to connect to an external control and evaluation unit, and a coil carrier, on which at least one primary coil and at least one first secondary coil are arranged circumferentially wound and spaced apart in an axial direction of an axis extending axially through the housing, wherein an end face of the coil carrier abuts an inner surface of the front cap, wherein the first secondary coil lies closer, in the axial direction, to the end face than the primary coil, wherein a second secondary coil, which is coiled or wound in an opposite direction to the first secondary coil, is arranged on the coil carrier, wherein the primary coil is arranged between the first and second secondary coils, wherein a metallic shielding element is arranged in an axial area surrounding the second secondary coil, and wherein the shielding element is not arranged in an axial area surrounding the first secondary coil.

### BRIEF DESCRIPTION OF THE DRAWINGS

Subject matter of the present disclosure will be described in even greater detail below based on the exemplary figures. All features described and/or illustrated herein can be used alone or combined in different combinations. The features and advantages of various embodiments will become apparent by reading the following detailed description with reference to the attached drawings, which illustrate the following:

FIG. 1 illustrates a proximity sensor as a vertical sectional representation,

FIG. 2 illustrates the proximity sensor from FIG. 2 as a horizontal sectional representation,

FIG. 3 illustrates an exploded drawing of the sensor according to FIGS. 1 and 2,

FIG. 4 illustrates a vertical sectional representation of a further proximity sensor with three coils,

FIG. 5 illustrates a vertical sectional representation of a further proximity sensor with printed secondary coils and a wound primary coil, and

FIG. 6 illustrates a vertical sectional representation of a further embodiment of a proximity sensor with three printed coils.

### DETAILED DESCRIPTION

On the whole, there is still a need for improvement with respect to the detection and switching distance of proximity sensors, with very compact and economical construction at the same time. In particular, a frequent problem is that the installation situation of a proximity sensor, through the use of metallic fastening or cover elements, leads to a partial shielding and thus to the alteration of the switching properties of the sensor. In an embodiment, the present invention thus provides a proximity sensor which has an increased switching distance, with improved installation properties, and which is constructed in a structurally simple manner.

The primary or transmitter coil and the at least one secondary coil are slightly spaced apart from each other in the direction of the axis. Ideally, in the case of wound coils, these are guided in grooves or indentations or arranged spaced apart from each other in a defined manner by circumferential bars. The coil carrier has an end face and a foot surface, wherein the end face of the coil carrier lies directly opposite the inner surface of the front cap and/or rests against it. Ideally, the end face of the coil carrier is connected, welded or adhered to the front cap. The first secondary coil here is arranged closer, in the axial direction, to the end face or directly adjoining it and the primary coil is arranged closer to the foot end.

The coil carrier is made of a non-conductive material, which has a low coefficient of expansion over the temperature range. In particular, the coil carrier is produced from a fibreglass-reinforced plastic and/or an epoxy resin.

In an embodiment, a second secondary coil, which is coiled or wound in the opposite direction, is provided on the coil carrier, and the primary coil is arranged between the two secondary coils. Furthermore, a metallic shielding element is arranged at least in the axial area of the second secondary coil and surrounding the latter, and no metallic shielding element is provided in the axial area of the first secondary coil which directly adjoins the end face or a sealing cap.

Here, by axis or axial direction is meant the theoretical, central axis (of symmetry) which is defined by the (printed) turns or windings of the coils and/or the geometry of the coil carrier.

In an advantageous embodiment, the metallic shielding element has a width which corresponds to at least one quarter of the height between the second secondary coil and the inner surface of the front cap, ideally the width corresponds to at least half of the height. The shielding element thus substantially overhangs the second secondary coil in the axial direction, without protruding into the detection area of the first secondary coil, whereby switching properties are optimally achieved.

There is an advantageous ratio between the height of the coil structure and the width of the shielding element if the width corresponds to 30% to 50% of the height of the coil structure.

A further improvement consists of the fact that the shielding element has a width such that the primary coil is also at least partially shielded in the axial direction, in particular is completely shielded. Depending on the desired switching characteristic, there is an improvement if the width of the shielding element is larger than the external spacing of the coils and/or only overhangs the respective coil edge in the axial direction towards the first secondary coil. The shielding element should in particular not protrude into the axial area of the front, first secondary coil, in order not to restrict its detection radius disadvantageously.

A partial shielding of coils of the wound or printed multi-coil system of the inductive proximity sensor is thus effected by shielding at least one of the coils used for the signal generation and/or evaluation. The proximity sensor can hereby be constructed and installed at a large, non-flush switching distance, yet flush in a metallic environment. A usual installation state is simulated by the circumferential shielding, with the result that the behaviour of the proximity sensor in a later “worst” installation situation is already simulated on the production side and can be measured on the laboratory side.

Through this structure, it is achieved that, with respect to the location relative to the individual coils, the internal partial shielding of the multi-coil system is placed precisely in the optimum axial position through the spacer. Thus, with the selected optimum coil diameter, the differential voltage forming is zeroed at the switching point set. Effects of metallic elements of the installation situation are thus largely neutralized and a large switching distance is achieved.

The advantage thus consists of the fact that the first secondary coil can be arranged in close, maximum proximity to the detection area, with the result that a wide radius is monitored and detected, while the effects of the and on the second secondary coil and optionally the primary coil are kept as small as possible. In this way, a very high level of detection precision and immunity with respect to external disruptive effects is achieved.

An improved design consists of joining the shielding element to the inner wall of the housing and/or the cap inner wall surrounding the second secondary coil or the pair consisting of second secondary coil and the primary coil at least in portions, with the result that as far as possible one and the same housing and shielding element can also be provided for different coil diameters, which are dimensioned depending on the respective detection tasks. It is advantageous to provide the maximum possible distance from the shielding element to in particular the second secondary coil by the latter resting for example against the inner wall of the housing or the front cap, wherein the diameter of the second secondary coil should be 60% to 70% of the diameter of the shielding element.

In an improved variant, at least one non-metallic, single- or multi-part spacer body, on which the shielding element rests and/or by which it is borne at least in portions, is arranged between the inner surface of the front cap and the shielding element. Variants of proximity sensors that are very easy to assemble and cost-effective can hereby be produced with different coil arrangements, in which the precise shielding of the primary coil can be very easily adapted. Ideally, the spacer body is a ring or collar, which is advantageously produced monolithically from plastic.

An advantageous embodiment consists of the fact that the coil carrier is designed annular and hereby has a free core and an inner wall. Here, annular means any elongated hollow shape, such as a tube section with any desired cross section, which is ideally round, however. The ring thickness in the circumferential direction and/or axial direction can vary. The gist of this embodiment is a carrier element to which the printed circuit board is directly or indirectly fastened. The carrier element here has a guiding and retaining portion, with which it rests against the inner wall of the coil carrier and/or via which it is fastened. In this way, a very compact and stable construction is generated, with a very good connection between the coil carrier and the printed circuit board or the processing and receiving unit. In particular, it can be easily preassembled accessible from all sides and subsequently inserted into the housing and/or onto the front cap.

A further improvement consists of the fact that the printed circuit board is connected to a connector element, or has one, via which the proximity sensor can be connected to external structures so as to carry data and/or current. As a rule, such external structures are data and/or power cables, which lead to components of a network, in particular an ethernet, a bus system, IO-Link or the like. The connector element advantageously has a group of two or more individual connectors arranged next to each other, wherein the individual connectors are ideally aligned parallel to the axis.

The connection of printed circuit board and coil carrier of the proximity sensor can be further improved if the connector element rests on the foot surface of the coil carrier at least in portions and here bridges the annular coil carrier and/or the connector element rests on a bar element of the carrier element or is fastened to it, and this bar element rests on the foot surface of the coil carrier at least in portions and partially bridges the annular coil carrier. The advantage of this design is a very stable support of the connector element while the installation space is as small as possible. The necessary force when attaching a connecting mating connector can be diverted onto the front cap in a straight line, whereby the assembly is greatly simplified.

Further details and advantages of the invention will now be explained in more detail with reference to embodiment examples represented in the drawings.

There are shown in:

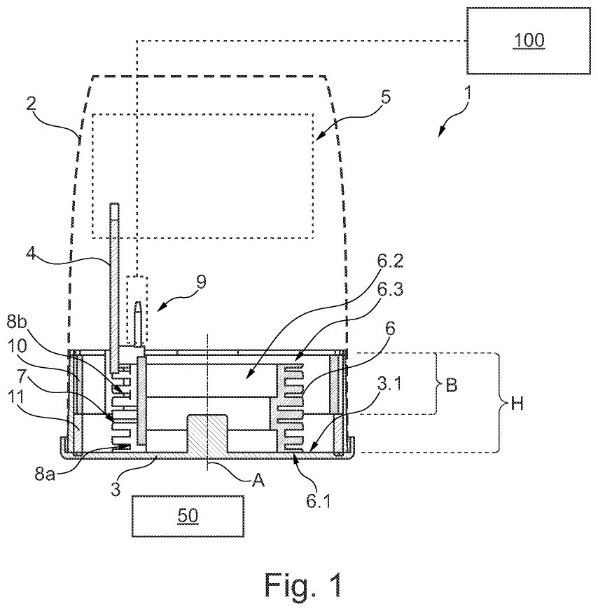

The proximity sensor 1 shown in FIG. 1 is aligned vertically downwards. The housing 2 sketched as a dashed line has, at the lower end, a front cap 3 to which the coil carrier 6 is attached centrally, which rests and is adhered with its end face 6.1 plane-parallel to the inner surface 3.1 of the front cap 3, or is fastened in a positive-locking and/or friction-locking manner. At least one upper, first secondary coil 8a and one second, lower secondary coil 8b are arranged in parallel grooves or channels of the coil carrier 6. A primary coil 7 (transmitter coil) is introduced between these two secondary coils 8a, b, which have windings oriented in opposite directions. Here, the location details in relation to gravity, such as in particular “top” or “bottom”, are not to be understood limitatively and serve only for illustration with reference to the respective representation. It is understood that the proximity sensor 1 can have any desired alignment, such as for example horizontal relative to the side, tilted, upwards or downwards, with the result that the details given herein are then to be understood analogously.

The coil carrier 6 is designed monolithically as a ring or collar and extends in the direction of the axis (of symmetry) A, around which the secondary coils 8a, b and the primary coil 7 are also arranged concentrically. The coil carrier 6 is optimized with respect to the necessary coil diameter and for this purpose has portions with different, free internal diameters in the axial direction A, with the result that the inner surface 6.2 has different rings or ring contours. Circumferential grooves or channels of different depths, in which the primary coil 7 and the secondary coils 8a, b among other things are also applied or introduced, are arranged on the outside. The mode of operation and interaction of the excited coils during the detection of an object 50 which appears in front of the free side of the proximity sensor 1 are fundamentally known to a person skilled in the art and therefore are not described in more detail.

A connector element 9, the individual connectors of which are aligned parallel to the axial direction A, is laid on the foot surface 6.3 of the coil carrier 6, with the result that no additional installation space is used up and vertical forces are diverted onto the front cap 3 via the coil carrier 6. This connector element 9 soldered to a printed circuit board 4 can be connected to an external control and evaluation unit 100. Here, by control and evaluation unit 100 is meant any external components and/or network to which the proximity sensor 1 can be connected so as to carry current and/or data.

The shielding element 10 produced from copper has a width B and is arranged circumferentially at the height of the primary coil 7 and the lower, second secondary coil 8b by laying it on a spacer body 11 designed as a plastic ring. In the embodiment example shown in FIGS. 1 to 4, the ratio between the width B of the shielding element and the height H of the coil structure is 45%; furthermore, the diameter of the shielding ring 10 is ⅓ larger than the diameter of the second secondary coil 8b.

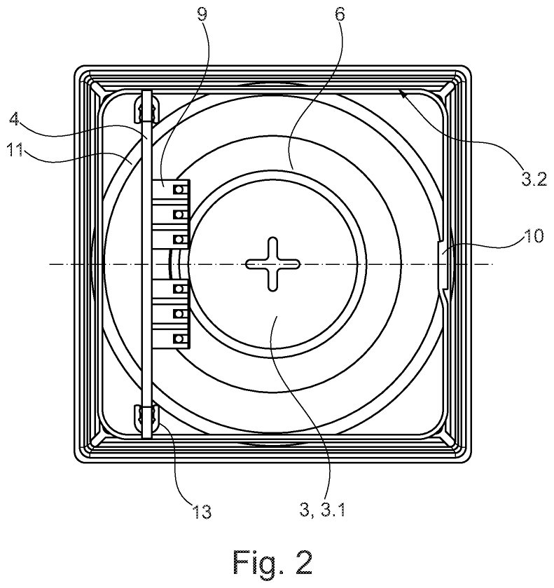

FIG. 2 shows the proximity sensor 1 according to FIG. 1 as a vertical sectional representation. It can be seen that the shielding element 10 is designed as a square frame which rests against the inner wall 3.2 of the front cap 3 surrounding the coil carrier 6 and is held by the round spacer body 11 in the necessary axial location. The printed circuit board 4 is oriented in terms of the length in the direction of the axis A and is laid on the foot surface 6.3 over the soldered connector element 9. In addition, the printed circuit board 4 is introduced and held in lateral guides 13, which are parts of the front cap 3. The compact construction and good accessibility of the connector element 9 when the housing 2 is opened can easily be seen.

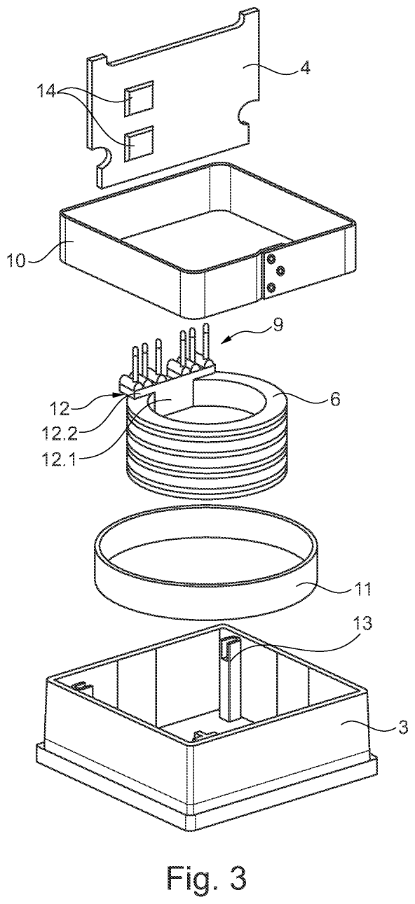

FIG. 3 shows the proximity sensor 1 according to FIGS. 1 and 2 as an exploded representation, so that the preceding statements apply analogously. In the representation according to FIG. 3, it can be seen that a carrier element 12 is provided, which has a guiding and retaining portion 12.1 at the lower end and an upper end which is formed as a bar element 12.2. The connector element 9 with the six individual connectors is attached to the bar element 12.2, which comes to rest on the foot surface 6.3 of the coil carrier 6 and partially bridges the free core. The guiding and retaining portion 12.1 of the carrier element 12 protrudes into the core of the coil carrier 6 in the axial direction and rests against its inner surface 6.2. In an embodiment, the bar element 12.2 and/or the guiding and retaining portion 12.1 are locked together with and/or adhered to the coil carrier 6. Two (micro)electronic components 14, which can be for example a μ-controller, a memory module, an ADC (analogue-to-digital converter) or the like, are indicated on the printed circuit board 4.

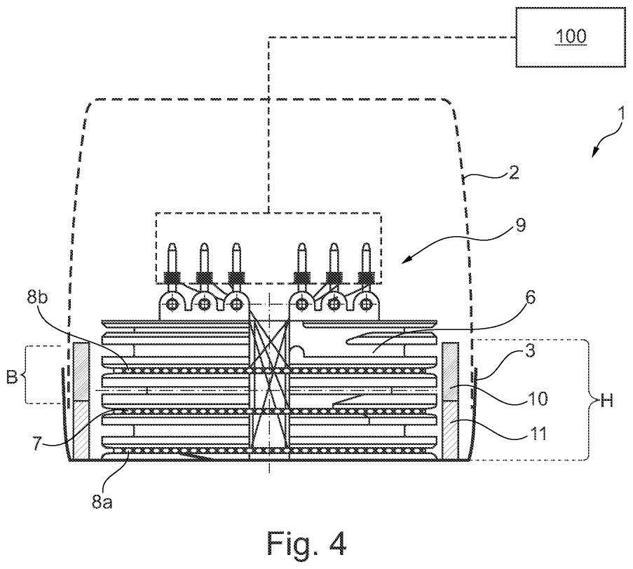

FIG. 4 shows a coil carrier on which the two secondary coils 8a, b, which have opposing winding directions, are arranged. The width B of the shielding element 10 is such that the primary coil 7 and the second secondary coil 8b are framed and shielded together, wherein the spacer element 11 manufactured from a non-shielding plastic is only arranged in the area of the first secondary coil 8a.

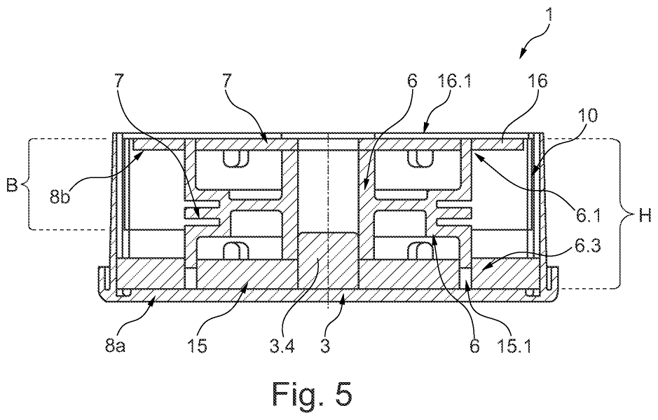

In the embodiment according to FIG. 5, the first secondary coil 8a is a printed coil, which is part of a first printed circuit board 15 fastened to the end face 6.1 of the coil carrier 6. The second secondary coil 8b is printed analogously, as part of a second printed circuit board 16 fastened to the foot surface 6.3.

The printed circuit boards 15, 16 have positioning holes 15.1, 16.1, in which receiving elements 6.4 of the central coil carrier 6 are introduced and fastened. In the embodiment example shown, the primary coil 7 is wound in grooves on the central coil carrier 6. The width of the shielding element 10 covers the second printed circuit board 16 with the printed, second secondary coil 8b and the wound primary coil 7 in the axial direction A.

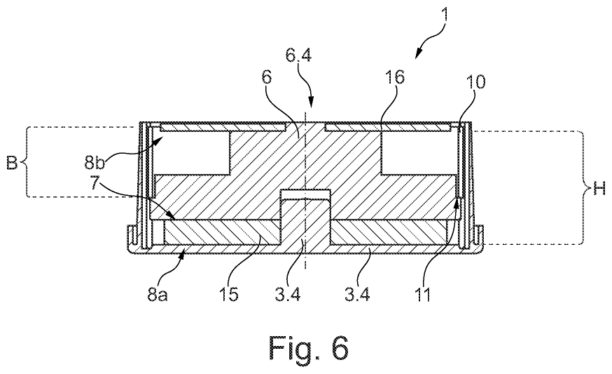

The positioning holes 15.1, 16.1 in the printed circuit boards 15, 16 can have any suitable geometry, in particular can also be formed as grooves or channels, wherein the respective receiving element 6.4 has a corresponding, complementary geometry. In the embodiments according to FIGS. 5 and 6, the front cap 3 has a centring element 3.4, which leads in a positive-locking manner into a complementary receiving opening both of the head-side first printed circuit board 15 and of the coil carrier 6, and if necessary is adhered or fastened.

FIG. 6 shows a vertical sectional representation of a further embodiment of a proximity sensor 1 with three printed coils 7, 8a, 8b. Here, the first secondary coil 8a and the primary coil 7 are arranged on the respectively opposite surfaces of a common printed circuit board 15, which, analogously to the embodiment of FIG. 5, rests on the inner surface 3.1 of the front cap 3 and is pierced and held by a central receiving element 3.4. The coil carrier 6 comprises the spacer body 11, which is formed monolithically as a circumferential ring, edge or a plurality of supporting bolts and on the upper edge of which the circumferential shielding element 10 is mounted. The second printed circuit board 16, on which the second secondary coil 8b is printed, has a central positioning hole 16.1, into which a central receiving element 6.4 of the coil carrier 6 is inserted. In both embodiment variants according to FIGS. 5 and 6, the width B is 50% of the height H.

While subject matter of the present disclosure has been illustrated and described in detail in the drawings and foregoing description, such illustration and description are to be considered illustrative or exemplary and not restrictive. Any statement made herein characterizing the invention is also to be considered illustrative or exemplary and not restrictive as the invention is defined by the claims. It will be understood that changes and modifications may be made, by those of ordinary skill in the art, within the scope of the following claims, which may include any combination of features from different embodiments described above.

The terms used in the claims should be construed to have the broadest reasonable interpretation consistent with the foregoing description. For example, the use of the article “a” or “the” in introducing an element should not be interpreted as being exclusive of a plurality of elements. Likewise, the recitation of “or” should be interpreted as being inclusive, such that the recitation of “A or B” is not exclusive of “A and B,” unless it is clear from the context or the foregoing description that only one of A and B is intended. Further, the recitation of “at least one of A, B and C” should be interpreted as one or more of a group of elements consisting of A, B and C, and should not be interpreted as requiring at least one of each of the listed elements A, B and C, regardless of whether A, B and C are related as categories or otherwise. Moreover, the recitation of “A, B and/or C” or “at least one of A, B or C” should be interpreted as including any singular entity from the listed elements, e.g., A, any subset from the listed elements, e.g., A and B, or the entire list of elements A, B and C.

### LIST OF REFERENCE NUMBERS

1 proximity sensor
2 housing
3 front cap
3.1 surface
3.2 inner wall
3.3 centring element
4 printed circuit board
5 processing and receiving unit
6 coil carrier
6.1 end face
6.2 inner surface
6.3 foot surface
6.4 receiving element
7 primary coil (transmitter coil)
8a secondary coil, first
8b secondary coil, second
9 connector element
10 shielding element
11 spacer body
12 carrier element
12.1 guiding and retaining portion
12.2 bar element
13 guide channel
14 component, (micro)electronic
15 printed circuit board, first
15.1 positioning hole
16 printed circuit board, second
16.1 positioning hole
50 object
100 control and/or evaluation unit
A axis
B width
H height

1. A proximity sensor for the inductive detection of objects, comprising:
a housing with a front cap, which forms a detection side of the proximity sensor;
a processing and receiving unit, comprising a printed circuit board, which is configured to connect to an external control and evaluation unit; and
a coil carrier, on which at least one primary coil and at least one first secondary coil are arranged circumferentially wound and spaced apart in an axial direction of an axis extending axially through the housing,
wherein an end face of the coil carrier abuts an inner surface of the front cap,
wherein the first secondary coil lies closer, in the axial direction, to the end face than the primary coil,
wherein a second secondary coil, which is coiled or wound in an opposite direction to the first secondary coil, is arranged on the coil carrier,
wherein the primary coil is arranged between the first and second secondary coils,
wherein a metallic shielding element is arranged in an axial area surrounding the second secondary coil, and
wherein the shielding element is not arranged in an axial area surrounding the first secondary coil.

2. The proximity sensor according to claim 1, wherein the shielding element is also arranged at least partially in an axial area surrounding the primary coil.

3. The proximity sensor according to claim 1, wherein a width of the shielding element in the axial direction towards the front cap is at least a factor of 0.25 of a height formed by a distance from the second secondary coil to the inner surface of the front cap.

4. The proximity sensor according to claim 1, wherein the shielding element abuts an inner wall of the housing or an inner wall of the cap surrounding the second secondary coil.

5. The proximity sensor according to claim 1, wherein the shielding ring abuts an inner wall of the front cap, and wherein a diameter of the second secondary coil is a factor of 0.6 to 0.7 of a diameter of the shielding element.

6. The proximity sensor according to claim 1, wherein at least one non-metallic, spacer body is arranged between the inner surface of the front cap and the shielding element, and wherein the shielding element abuts the spacer body or is at least partially borne by the spacer body.

7. The proximity sensor according to claim 1, wherein the spacer body is a plastic ring or a collar.

8. The proximity sensor according to claim 1, wherein the coil carrier has an annular configuration and has an inner wall, and wherein the printed circuit board is fastened to a carrier element, the carrier element having a retaining portion configured to abut against or fasten to the inner wall of the coil carrier.

9. The proximity sensor according to claim 1, wherein the printed circuit board is connected to a connector element via which the proximity sensor can be connected to external structures to carry data or current.

10. The proximity sensor according to claim 9, wherein the connector element comprises a group of two or more individual connectors arranged adjacent to each other, wherein the individual connectors are aligned parallel to the axial direction.

11. The proximity sensor according to claim 9, wherein:
the connector element abuts a foot surface arranged opposite the end face of the coil carrier and bridges the coil carrier, or
the connector element abuts or is fastened to a bar element of a carrier element, the bar element abutting the foot surface of the coil carrier and bridging the coil carrier.

12. The proximity sensor according to claim 3, wherein the width of the shielding element in the axial direction towards the front cap is a factor of 0.3 to 0.5 of the height.

13. The proximity sensor according to claim 1, wherein the shielding element abuts an inner wall of the housing or an inner wall of the cap surrounding at least a portion of both the second secondary coil and the primary coil.
